(19) United States
(12) Patent Application Publication
(10) Pub. No.: US 2002/0015234 A1
(43) Pub. Date: Feb. 7, 2002

(54) Apparatus for moving optical functioning element

(76) Inventors: Makoto Suzuki, Chiba-shi (JP); Akihiro Iino, Chiba-shi (JP); Masao Kasuga, Chiba-shi (JP)

Correspondence Address: ADAMS & WILKS, 31st Floor, 50 Broadway, New York, NY, 10004, US

(21) Appl. No.: 09/796,152

(22) Filed: Feb. 28, 2001

(30) Foreign Application Priority Data
Mar. 3, 2000 (JP) 2000-058500
Feb. 2, 2001 (JP) 2001-026369

(51) Int. Cl. G02B 15/14; H01L 41/04

(52) U.S. Cl. 359/683; 310/328; 359/684

(57) ABSTRACT

The invention relates to an apparatus for moving an optical functioning element at sufficient accuracy over a long period of use or in a case where the temperature changes, in which a voltage is applied only when moving an optical functioning element, wherein a moving member 4, which moves forward and rearward in one direction by a guiding member 5, and one end of an optical filter main body 41, which is fixed at the moving member 4, are brought into contact with the circumferential surface of a disk-shaped eccentric cam 3 that rotates by an ultrasonic motor 2, and a coil spring 6 is brought into contact with the other end of the optical filter main body 41, whereby pressing the moving member 4 to the eccentric cam 3 side. Also, the apparatus includes a position signal generating means that generates a signal to detect the position of the optical filter main body 41 and a controller that controls the ultrasonic motor 2 in compliance with the signal inputted from the position signal generating means and inputting means.

### BACKGROUND OF THE INVENTION

1. Field of the Invention

The present invention relates to an apparatus for moving an optical functioning element, which moves to an appointed position by a piezoelectric actuator.

2. Description of the Prior Art

It is necessary that a wavelength-varying optical filter, variable attenuator, and optical switch in a wavelength multiplexed optical communication are accurately moved to an appointed position in order to display the performance thereof.

Conventionally, for example, a wavelength-varying optical filter uses a piezoelectric element, or as described in Japanese Patent Publication No. 2874635, they are moved by using a piezoelectric body.

The technology disclosed by Japanese Patent Publication No. 2874635 is as follows;

That is, after a piezoelectric body is returned to an initial state as a preliminary action, a wavelength-varying optical filter is moved by the piezoelectric body, and a drive voltage when an appointed penetration wavelength is obtained is stored. And, by applying the stored drive voltage after the piezoelectric body is returned to the initial state, the wavelength-varying optical filter is moved to an appointed position, whereby an appointed penetration wavelength can be obtained.

As has been represented by Japanese Patent Publication No. 2874635 described above, a conventional type in which a piezoelectric actuator is employed was used to move a wavelength-varying optical filter by utilizing the elongation and contraction of a piezoelectric body as they are. Therefore, when locating the wavelength-varying optical filter at a position other than the initial state, it was necessary to always apply voltage to a piezoelectric actuator even when it is not driven. Therefore, the running cost thereof was expensive.

Also, the piezoelectric element deteriorates due to long termuse, wherein even though the same voltage is applied thereto, the piezoelectric element does not necessarily elongate or contract by the same distance. For this reason, in the technology disclosed by the above-described publication, it was difficult to continuously display appointed performance where the piezo electric element is used in a communication facility, etc., for a long period of time, and there was a possibility that sufficient reliability cannot be obtained.

Further, since the characteristics of a piezoelectric element changes due to the temperature in the environment where used, the piezoelectric element does not necessarily elongate or contract by the same distance even though the same voltage is applied thereto. In the technology disclosed by the above-described publication, there was a possibility that sufficient level of technology cannot be obtained even before it deteriorates.

It is therefore an object of the present invention to provide an apparatus for moving an optical functioning element using a piezoelectric actuator to which voltage is applied only when moving the optical functioning element. Also, it is another object of the invention to provide an apparatus for moving an optical functioning element, which can move at high accuracy even after it has been used for a long time or even when the temperature changes.

### SUMMARY OF THE INVENTION

In order to achieve the objects, an apparatus for moving an optical functioning element is featured in that the apparatus comprises a piezoelectric actuator for moving an optical functioning element, which differs based on a stationary position, by using the vibration generated in a piezoelectric vibrating body as a power source; and a means for positioning the optical functioning element by controlling the piezoelectric actuator.

As a detailed moving mechanism of a piezoelectric actuator according to the invention, there are a mechanism in which an eccentric cam and a shaft is utilized, a mechanism in which a rack pinion and a gear are utilized, a mechanism in which friction is used, etc. Further, an output projection that outputs vibration of the piezoelectric vibrator by amplifying the same may be used as it is.

According to the invention, an optical functioning element moves by using the vibration of a piezoelectric vibrator as a power source. Therefore, even though the vibration stops due to no voltage being applied to a piezoelectric element and the piezoelectric element is returned to its initial state, the optical functioning element may remain as it is, and it does not return to its original point.

Therefore, voltage may be applied only when moving the optical functioning element, wherein the running cost thereof can be suppressed to be low.

The apparatus for moving an optical functioning element includes a means for detecting the position of the optical functioning element and a means for controlling a piezoelectric vibrator by using signals from the position detecting means, wherein since the piezoelectric vibrator is controlled while detecting the position of the optical functioning element as per action, the optical functioning element can be moved to an appointed position without fail even though the piezoelectric body in the piezoelectric vibrator deteriorates or its characteristics change due to a change in temperature.

### BRIEF DESCRIPTION OF THE DRAWINGS

FIG. 1 is a plane view of an optical filter moving apparatus according to the first embodiment;

FIG. 2 is a side view of the optical filter moving apparatus of FIG. 1;

FIG. 3 is a rough perspective view of an optical filter body of the optical filter moving apparatus of FIG. 1;

FIG. 4 is a block diagram showing the major parts of the optical filter moving apparatus of FIG. 1;

FIG. 5 is a plane view of an optical filter moving apparatus according to the second embodiment, to which the invention is applied;

FIG. 6 is a side view of the optical filter moving apparatus of FIG. 5;

FIG. 7 is a plane view of an optical filter moving apparatus according to the third embodiment, to which the invention is applied;

FIG. 8 is a side view of the optical filter moving apparatus of FIG. 7;

FIG. 9 is a plane view of an optical filter moving apparatus according to the fourth embodiment, to which the invention is applied;

FIG. 10 is a plane view of an optical filter moving apparatus according to the fifth embodiment, to which the invention is applied;

FIG. 11 is a rough perspective view of a modified version of the optical filer body of the optical filter moving apparatus;

FIG. 12 is a sectional view describing a modified version of an ultrasonic motor of the optical filter moving apparatus;

FIG. 13 is a plane view of an optical switch according to the sixth embodiment, to which the invention is applied;

FIG. 14 is a plane view of a variable attenuator according to the seventh, embodiment, to which the invention is applied; and

FIG. 15 is a side view of the variable attenuator of FIG. 14.

### DETAILED DESCRIPTION OF EMBODIMENTS OF THE INVENTION

Hereinafter, a detailed description is given of the invention with reference to the accompanying drawings.

### Embodiment 1

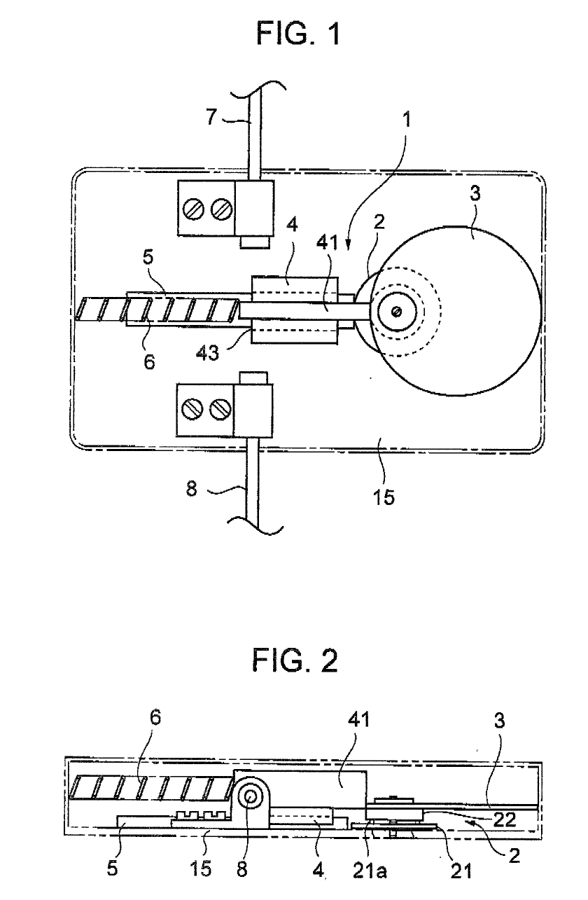

A description is given of an optical filter moving apparatus 1 that is an example of the apparatus for moving an optical functioning element according to the first embodiment of the invention, with reference to FIG. 1 through FIG. 4.

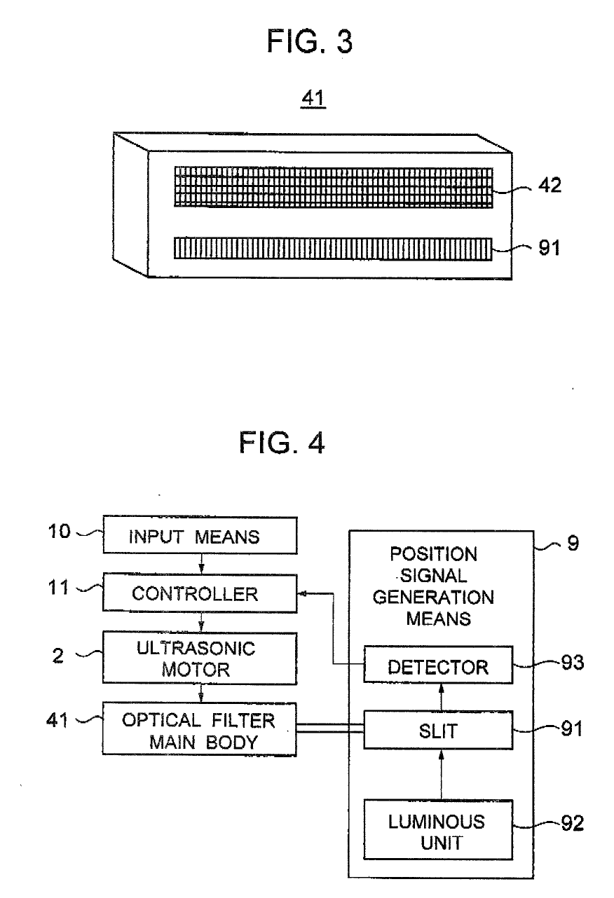

As shown in FIG. 1 and FIG. 2, the optical filter moving apparatus 1 is constructed so that a member 4 that moves forward and rearward in one direction by a guiding member 5 and one end of an optical filter main body 41 that is fixed on the moving member 4 and moves in synchronization therewith are brought into contact with the circumferential surface of a disk-shaped eccentric cam 3 that rotates by an ultrasonic motor 2, a coil spring 6 (a pressing means) is brought into contact with the other end of the optical filter main body 41, and the optical filter main body 41 is pressed to the eccentric cam 3 side. That is, as shown in FIG. 3, the optical filter moving apparatus 1 is installed so that a wavelength-varying optical filter 42 of the optical filter main body 41 is disposed between an optical fiber 7 and an optical fiber 8, and can transmit light of only the appointed wavelength of the wavelength multiplexed light emitted from the optical fiber 7 by moving the a wavelength-varying optical filter 42 to an appointed position forward and rearward so as to make the light incident to the optical fiber 8.

Also, the optical filter moving apparatus 1 includes, as shown in FIG. 4, a position signal generating means 9 that generates a signal for detecting the amount of movement of the optical filter main body 41, and a controller 11 that controls the ultrasonic motor 2 in compliance with a signal inputted from the position signal generation means 9 and inputting means 10.

The ultrasonic motor 2 includes a piezoelectric vibrator 21 and a rotor 22 that is rotatably installed on the output projection 21a on the upper surface of the piezoelectric vibrator 21, and the construction thereof is roughly equivalent to that of a publicly known ultrasonic motor.

The piezoelectric vibrator 21 is constructed so that a vibrator for amplifying vibration, which is provided with the output projection 21a on the upper surface thereof, is fixed on the piezoelectric body that produces bending vibration in compliance with an inputted drive voltage.

The optical filter main body 41 is a parallelepiped member as shown in FIG. 3, which holds an already known wavelength-varying optical filter 42 in a state where the filter 42 is exposed from the side opposite thereto, and it is constructed so that a slit 91, which is a part of the position signal generating means 9 (the detail of which is described later), is held parallel to the wavelength-varying optical filter 42.

The moving member 4 has a roughly channel-shaped section, which is provided with a groove 43 below the underside of a rough parallelepiped, and has the optical filter 41 fixed thereon. Since the moving member 4 is accommodated in the guiding member 5 and slidably held therein, the member 4 slides to the center of rotation of the ultrasonic motor 2.

As shown in FIG. 4, the position signal generating means 9 is roughly composed of a slit 91, a luminescent part 92 that emits light to the slit 91, and a detector 93 for converting light, which is from the luminescent part 92 and is transmitted through the slit 91, to a pulse signal and outputs it to the controller 11. Herein, the luminous unit 92 and detector 93 are fixed in, for example, a casing 15 so that their positions are not changed.

The inputting means 10 is, for example, a keyboard or other control circuit, etc. The means 10 outputs a signal, which shows a wavelength to be transmitted by the wavelength-varying optical filter 42, to the controller 11.

The controller 11 calculates pulse signals from the luminescent part 92, converts the same to the amount of movement and position of the moving member 4, identifies the wavelength of light that the wavelength-varying optical filter 42 transmits, compares the wavelength with the wavelength inputted from the inputting means 10, and controls the ultrasonic motor 2, whereby the position of the optical filter main body 41, that is, the wavelength-varying optical filter 42 is moved to an appointed position.

Next, a description is given of the actions of the optical filter moving apparatus 1.

As the ultrasonic motor 2 rotates counterclockwise (or clockwise) in FIG. 1, the eccentric cam 3 also rotates counterclockwise (or clockwise) in FIG. 1. In this case, the optical filter main body 41 and moving member 4 are pressed by the end face of the eccentric cam 3, and overcome the pressing force of the coil spring 6, wherein they move to the leftward side in FIG. 1.

After that, as the ultrasonic motor 2 rotates in the opposite direction, the eccentric cam 3 rotates in the opposite direction, wherein the eccentric cam 3 stops pressing the optical filter main body 41. In this case, the moving member 4 and optical filter main body 41 move to the rightward side by the pressing force of the coil spring 6.

Therefore, according to the optical filter moving apparatus 1, by causing the eccentric cam 3 to rotate by driving the ultrasonic motor 2, the wavelength-varying optical filter 42 is caused to move to an appointed position.

Further, the ultrasonic motor 2 uses the bending vibration produced in the piezoelectric body as its drive power source, wherein the rotor 22 is not returned to its original point after the drive is stopped. Accordingly, since the drive voltage is required only when moving the wavelength optical filter 42, the power consumption can be remarkably decreased, compared with the prior arts.

In addition, since the wavelength-varying optical filter 42 and slit 91 are provided integrally with the optical filter main body 41 and the ultrasonic motor 2 is controlled while detecting the position of the wavelength-varying optical filter 42 by using the slit 91, the wavelength-varying optical filter 42 is disposed at an appointed position without fail even it the characteristics of the ultrasonic motor 2 deteriorates through a long period of use or a change in line with a change in the temperature, wherein it is possible to transmit an adequate wavelength of light.

### Embodiment 2

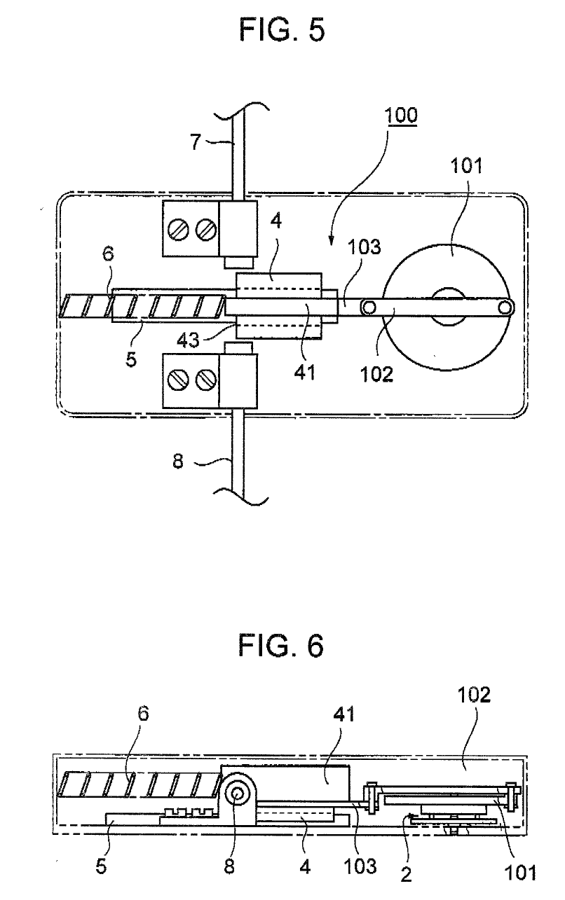

Next, a description is given of an optical filter moving apparatus 100, which is one of the examples of an apparatus for moving an optical functioning element, according to the second embodiment of the invention with reference to FIG. 5 and FIG. 6.

As shown in FIG. 5 and FIG. 6, the optical filter moving apparatus 100 is constructed roughly equivalently to the construction of the optical filter moving apparatus 1. However, the second embodiment is constructed so that a rotating plate 101 (rotating body) and a shaft 102 are provided instead of the eccentric cam 3, and a holding plate 103 is provided between the optical filter 41 and the moving member 4.

The rotating plate 101 is a disk concentrically fixed on the rotor 22 of an ultrasonic motor 2.

The shaft 102 has one end rotatably incorporated in the circumferential edge of the rotating plate 101 and the other end rotatably Incorporated at the end part of the holding pate 103.

In the optical filter moving apparatus 100 thus constructed, as the ultrasonic motor 2 rotates counterclockwise (or clockwise) in FIG. 5, the rotating plate 101 rotates while pressing the shaft 102 and moving member 4 to the leftward side in FIG. 5.

After that, as the ultrasonic motor 2 rotates n the opposite direction, the rotating plate 101 rotates while returning the shaft 102 and moving member 4 to the rightward side.

Therefore, according to the optical filter moving apparatus 100, effects similar to those of the optical filter moving apparatus 1 can be brought about.

### Embodiment 3

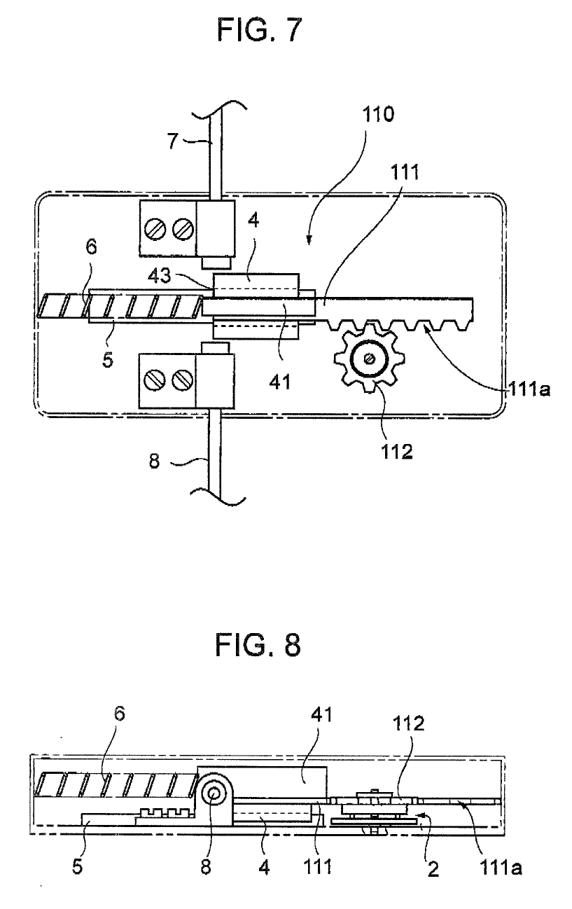

Next, a description is given of an optical filter moving apparatus 110, which is one of the examples of an apparatus for moving an optical functioning element, according to the third embodiment of the invention with reference to FIG. 7 and FIG. 8.

As shown in FIG. 7 and FIG. 8, the optical filter moving apparatus 110 is constructed roughly equivalently to the construction of the optical filter moving apparatus 1.

However, the optical filter moving apparatus 110 is not provided with any eccentric cam 3, but it is constructed so that a moving plate 111 is incorporated between the optical filter main body 41 and the moving member 4 so that one end thereof jumps from the moving member 4, a rack pinion 111a is formed at one end side of the moving plate 111, and a gear 112, which rotates by the ultrasonic motor 2, is engaged with the rack pinion.

In the optical filter moving apparatus 110 thus constructed, as the ultrasonic motor 2 rotates counterclockwise in FIG. 7, the gear 112 rotates so as to move the rack pinion 111a and moving member 4 to the leftward side in FIG. 7.

To the contrary, as the ultrasonic motor 2 rotates clockwise in FIG. 7, the gear 112 rotates so as to move the rack pinion 111a and moving member 4 to the rightward side in FIG. 7.

At this time, since the moving member 4 and rack pinion 111a are pressed to the rightward side in FIG. 7 by the coil spring 6 via the optical filter main body 41, no play between the rack pinion 111a and gear 112 adversely influence the positional accuracy of the moving member 4.

Accordingly, according to the optical filter moving apparatus 110, effects similar to those of the optical filter moving apparatus 1 can be brought about.

### Embodiment 4

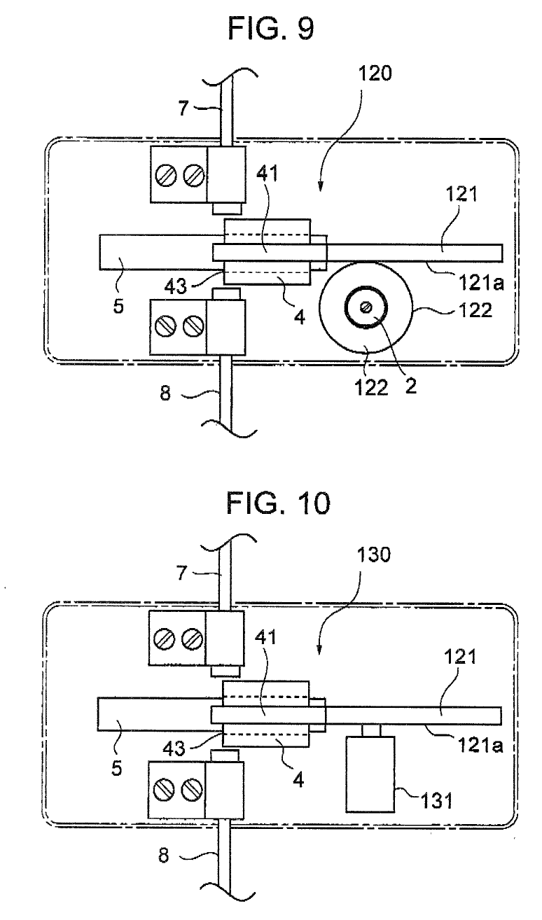

Next, a description is given of an optical filter moving apparatus 120, which is one of the examples of an apparatus for moving an optical functioning element, according to the fourth embodiment of the invention with reference to FIG. 9.

As shown in FIG. 9, the optical filter moving-apparatus 120 is constructed roughly equivalently to the optical filter moving apparatus 1. However, the optical filter moving apparatus 120 is not provided with any eccentric cam 3 and coil spring 6, but it is constructed so that a roughly square post-like sub member 121 (a part of the moving member) is incorporated between the optical filter main body 41 and the moving member 4 so as for one end side thereof to jump from the moving member 4, and the side face 122a of a disk-shaped rotating body 122, which rotates by the ultrasonic motor 2, is brought into contact with the side face 121a at one end side of the sub member 121.

That is, the rotating force of the ultrasonic motor 2 is transmitted to the moving member 4 by a friction force between the side face 121a and the side face 122a. Therefore, the side faces 121a and 122a are produced so as to have a high friction coefficient or are made of a material having a high friction coefficient. For example, silicon rubber and hard rubber, etc., are considered to be available as a material having a high friction coefficient. By attaching these materials to the respective side faces, the above construction can be brought about.

In addition, it is possible to form a film of a material having characteristics equivalent to the above-described materials. In this case, the film may be formed by spraying or immersing.

In the optical filter moving apparatus 120 thus constructed, as the ultrasonic motor 2 and rotating body 122 rotate counterclockwise in FIG. 9, the sub member 121 and moving member 4 move to the leftward side in FIG. 9. Also, as the ultrasonic motor 2 and rotating body 122 rotate clockwise in FIG. 9, the sub member 121 and moving member 4 move to the rightward side in FIG. 9.

Therefore, according to the optical filter moving apparatus 120, effects similar to those of the optical filter moving apparatus 1 can be brought about.

### Embodiment 5

Next, an optical filter moving apparatus 130, which is one of the examples of an apparatus for moving an optical functioning element, according to the fifth embodiment of the invention is described with reference to FIG. 10.

As shown in FIG. 10, the optical filter moving apparatus 130 is constructed roughly equivalently to the optical filter moving apparatus 120. However, the apparatus 130 is provided with a linear type ultrasonic motor 131 instead of the ultrasonic motor 2 and rotating body 122.

The linear type ultrasonic motor 131 is an ultrasonic motor in which a bending vibration produced at the side of a piezoelectric element having a plurality of polarization areas disposed so as for the polarity thereof to be secured alternately is used as a drive power source, and has an output projection 131a at the side face thereof.

That is, the optical filter moving apparatus 130 is constructed so that the output projection 131a of the linear type ultrasonic motor 131 is brought into contact with the side face 121a of the sub member 121.

In the optical filter moving apparatus 130 thus constructed, since the linear type ultrasonic motor 131 transmits a drive force to the sub member 121 via the output projection 131a, the sub member 121 and moving member 4 are caused to move to the right and left directions in FIG. 10.

Therefore, according to the optical filter moving apparatus 130, effects similar to those of the optical filter moving apparatus 1 can be brought about.

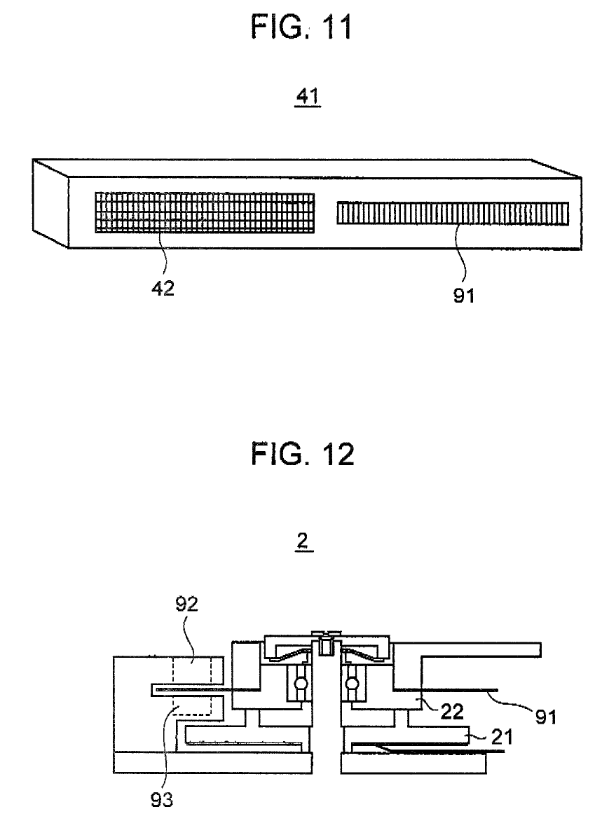

Also, in the respective optical filter moving apparatuses described above, although the wavelength-varying optical filter 42 and slit 91 are installed so as to be arranged up and down in the optical filter 41, the present invention is not limited to this mode. For example, as shown in FIG. 11, the wavelength-varying optical filter 42 and slit 91 may be installed so as to be arranged horizontally.

In addition, as shown in FIG. 12, the slit 91 is not secured at the optical filter main body 41, but is attached to the outer circumference of the rotor 22 of the ultrasonic motor 2, wherein the controller 11 calculates the amount of rotation of the ultrasonic motor 2, and the amount of movement of the moving member 4 can be calculated on the basis of the amount of rotation.

Also, in the optical filter moving apparatuses 100 and 110, it is constructed that the coil spring 6 presses the moving member 4 via the optical filter main body 41 or pull sit therefrom.

It is needless to say that other detailed constructions may be adequately altered within the scope that does not depart from the spirit of the invention.

### Embodiment 6

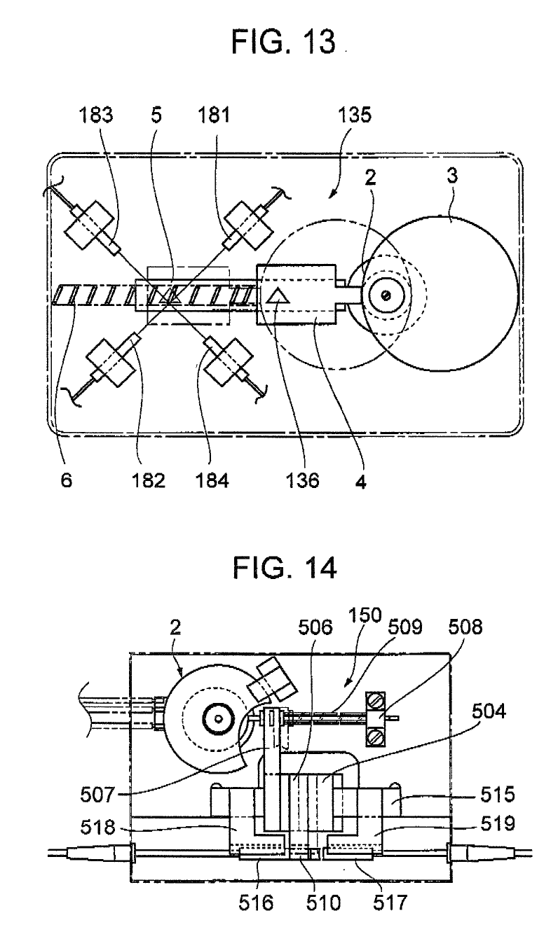

A description is given of an optical switch 135, which is one of the examples of an apparatus for moving an optical functioning element, according to the sixth embodiment of the invention with reference to FIG. 13.

As shown in FIG. 13, although the optical switch 135 is constructed roughly equivalently to the optical filter moving apparatus 1, it is constructed so that at least four optical fibers are provided, two optical fibers are disposed so as to be opposed to each other, and a mirror 136 is provided instead of the optical filter main body 41.

In the optical switch 135 thus constructed, when the moving member 4 is located at the right side in FIG. 13, the optical fiber A 181 faces the optical fiber B 182, and the optical fiber C 183 faces the optical fiber D 184, where, for example, the optical fiber A 181 and optical fiber D 184 are at the light-emitting side, the optical fiber B 182 and optical fiber C 183 are located at the light receiving side.

Also, when the moving member 4 is located at the left side in FIG. 13, light is reflected by the mirror 136 secured at the moving member 4. For example, if the light-emitting side is set at the optical fiber A 181 and optical fiber D 184, the optical fiber C 183 receives the light of the optical fiber A 181, and the optical fiber 182 B receives the light of the optical fiber D 184.

Therefore, according to the optical switch 135, the light emitted from an optical fiber can be varied in a plurality of directions by whether or not the mirror 136 is provided. For example, according to the construction shown in FIG. 13, two by two optical switches are enabled.

### Embodiment 7

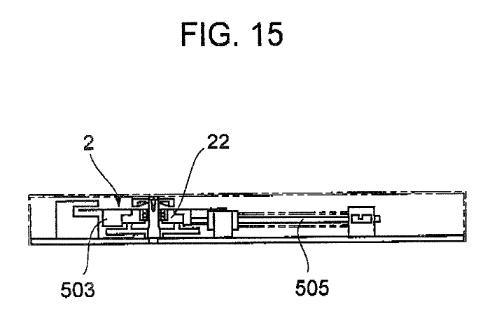

Next, a description is given of an variable attenuator 150, which is one of the examples of an apparatus for moving an optical functioning element, according to the seventh embodiment of the invention with reference to FIG. 14 and FIG. 15.

As shown in FIG. 14 and FIG. 15, the variable attenuator 150 is constructed so that it presses a shaft 505 to the eccentric cam 503 side by the shaft 505, one end of which is brought into contact with the circumferential surface of a disk-shaped eccentric cam 503 rotated by an ultrasonic motor 202; a guiding member 508 for slidably holding the other end of the shaft 505; a plate 507, one end of which fixes the shaft 505, and the other end of which is fixed at a moving member 504; a lens fixing plate 506, one end of which is fixed at the moving member 504, and at the other end of which a lens 510 is fixed; an optical element fixing member A 518, one end of which is fixed in the vicinity of one end of the guiding member 515, and at the other end of which a collimator A 516 is fixed; an optical element fixing member B 519, one end of which is fixed in the vicinity of the other end of the guiding member 515, and at the other end of which a collimator B 517 is fixed; and a coil spring 509 (pressing means) incorporated in the outer circumference of the shaft 505 between the plate 507 and the guiding member 508.

That is, the variable attenuator 150 attenuates light by moving the lens 510, which is disposed between the collimator A 516 and collimator B 517 that are fixed so as to be faced to each other, in the right and left directions on the optical axis.

In addition, the variable attenuator 150 is constructed so that it calculates the amount of movement of the lens 510 as in FIG. 12.

Therefore, according to the variable attenuator 150, the lens 510 can be moved to an appointed position by driving the ultrasonic motor 2 and rotating the eccentric cam 503.

Further, the ultrasonic motor 2 uses bending vibration produced at a piezoelectric body as a drive power source and the rotor 22 does not return to its original point after the movement stops. Therefore, since a drive voltage is required only when moving the lens 510, the power consumption can be remarkably reduced in comparison with the prior arts.

Still further, the variable attenuator 150 may be constructed so that, in order to attenuate light, a collimator A 516 and a collimator B 517 are not used, no optical element fixing member B 519 is provided, an optical fiber is fixed directly at the optical element fixing member A 518 and lens fixing plate 506, and the lens fixing plate 506 is moved in the right and left directions.

According to the invention, since an optical functioning element is caused to move by using the bending vibration of a piezoelectric vibrator as a drive power source, it is enough that voltage is applied only when moving the optical functioning element, wherein the running cost thereof can be suppressed.

In addition, since an apparatus for moving an optical functioning element is provided with a position detecting means that detects the position of the above-described optical functioning element, and a controlling means that controls the piezoelectric vibrator by using signals from the position detecting means, and the piezoelectric vibrator is controlled while detecting the position of the optical functioning element as per action, it is possible to securely move the optical functioning element to an appointed position even if the piezoelectric body in the piezoelectric vibrator deteriorates and the characteristics changes due to a change in temperature.

What is claimed is:

1 An apparatus for moving an optical functioning element, comprising:
a piezoelectric actuator for moving an optical functioning element by using vibration generated at a piezoelectric vibrating body as a power source; and
a means for positioning the optical functioning element by controlling the piezoelectric actuator.

2. The apparatus for moving an optical functioning element according to claim 1, further comprising:
an eccentric cam that rotates by the vibration of the piezoelectric vibrator;
a moving member that holds an optical functioning element, one end of which is in contact with the eccentric cam;
a guiding member that holds the moving member slidably in the forward and rearward directions; and
a means for pressing the optical functioning element to the eccentric cam.

3. The apparatus for moving an optical functioning element according to claim 1, further comprising:
a moving member that holds the optical functioning element;
a guiding member that holds the moving member slidably in the forward and rearward directions;
a rotating body that rotates by the vibration of the piezoelectric vibrator; and
a shaft, one end of which is rotatably assembled to the rotating body, and the other end of which is rotatably assembled to the end part of the moving member.

4. The apparatus for moving an optical functioning element according to claim 1, further comprising:
a moving member that holds the optical functioning element and is provided with a rack pinion at a part thereof;
a guiding member that holds the moving member slidably in the forward and rearward directions; and
a gear that is engaged with the rack pinion and rotates by the vibration of the piezoelectric vibrator.

5. The apparatus for moving an optical functioning element according to claim 3, further comprising: a means for pressing the moving member in one direction.

6. The apparatus for moving an optical functioning element according to claim 4, further comprising: a means for pressing the moving member in one direction.

7. The apparatus for moving an optical functioning element according to claim 1, further comprising:
a moving member that holds the optical functioning element, in which at least a part of the surface part thereof is made so as to have a high friction coefficient:
a guiding member that holds the moving member slidably in the forward and rearward directions; and
a rotating body that rotates by the vibration of the piezoelectric vibrator and transmits a rotating force to the moving member as linear movement by a friction force by being brought into contact with the part of the moving member that is made so as to have a high friction coefficient.

8. The apparatus for moving an optical functioning element according to claim 1, further comprising
a moving member that holds the optical functioning member; and
an output projection that is installed on the vibration surface of the piezoelectric vibrator and directly drives the moving member by amplifying the vibration of the corresponding piezoelectric vibrator.

9. The apparatus for moving an optical functioning element according to claim 1, further including a means for detecting the position of the optical functioning element and a means for controlling a piezoelectric vibrator by using signals from the means for detecting the position as the positioning means.

10. The apparatus for moving an optical functioning element according to claim 9, wherein the position detecting means includes a means for detecting the amount of movement of a piezoelectric actuator; and
a means for calculating the position of the optical functioning element on the basis of a detected value of the means for detecting the amount of movement of the actuator.

11. The apparatus for moving an optical functioning element according to claim 9, further comprising:
a means for detecting the amount of movement of the optical functioning element; and
a means for calculating the position of the optical functioning element on the basis of a detected amount obtained by the means for detecting the amount of movement of the actuator.

12. The apparatus for moving an optical functioning element according to any one of claims 1 through 11, wherein the optical functioning element is applied to a filter, collimator, fiber, lens, and mirror.
